(19) United States
(12) Patent Application Publication
(10) Pub. No.: US 2024/0097081 A1
(43) Pub. Date: Mar. 21, 2024

(54) LIGHT EMITTING DIODE WITH INCREASED LIGHT CONVERSION EFFICIENCY

(71) Applicant: Applied Materials, Inc., Santa Clara, CA (US)

(72) Inventors: Jiacheng Fan, Los Angeles, CA (US); Zhiyong Li, Foster City, CA (US)

(73) Assignee: Applied Materials, Inc., Santa Clara, CA (US)

(21) Appl. No.: 18/468,091

(22) Filed: Sep. 15, 2023

Related U.S. Application Data
(60) Provisional application No. 63/406,937, filed on Sep. 15, 2022.

(51) Int. Cl. H01L 33/50

(52) U.S. Cl. CPC H01L 33/502

(57) ABSTRACT

Embodiments of the present technology include pixel structures. The pixel structures include a light emitting diode structure to generate ultraviolet light. The pixel structures further include a photoluminescent region containing a photoluminescent material. The pixel structures additionally include a first bandpass filter positioned between the light emitting diode structure and the photoluminescent region, where the first bandpass filter is operable to transmit greater than 50% of light having a wavelength less than or about 400 nm. The pixel structures yet additionally include a second bandpass filter positioned on an opposite side of the photoluminescent region as the first bandpass filter, where the second bandpass filter is operable to transmit greater than 50% of light having a wavelength greater than 400 nm.

### CROSS-REFERENCE TO RELATED APPLICATIONS

This application claims the benefit of U.S. Provisional Patent Application No. 63/406,937, filed on Sep. 15, 2022, entitled “Light Emitting Diode With Increased Light Conversion Efficiency”, the contents of which is hereby incorporated by reference in its entirety for all purposes.

### FIELD

The present technology relates to displays having pixel structures with a light-emitting-diode (LED) structure combined with a photoluminescent region containing photoluminescent materials. Exemplary photoluminescent materials include quantum dots.

### BACKGROUND

High-resolution light-emitting diode (LED) displays can include millions of micron-sized pixels arranged to form a viewing screen. Conventional LED displays generate a color image by filtering down white light from an LED light source into red, green, and blue pixels that emit at varying intensities across the viewing screen. Other LED displays excite organic or inorganic compounds, so they emit light of a particular color, such as red, green, or blue light, depending on the pixel. These LED displays typically require fewer filters to block the light of unwanted colors and can produce a more accurate color gamut. However, many photoluminescent materials have relatively low conversion efficiencies between the excitation light and the visible light of interest. They also can emit and scatter the light in all directions. These characteristics of the light emitting compounds can reduce the brightness of the displayed images.

Thus, there is a need for pixel designs that generate brighter images for display devices that include excitable light-emitting materials. These and other needs are addressed by the present technology.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 shows a flowchart with selected operations of an exemplary method of fabricating a pixel structure according to embodiments of the present technology.

FIG. 2 shows a simplified cross-sectional view of an exemplary single pixel structure according to embodiments of the present technology.

FIG. 3 shows a simplified cross-sectional view of an exemplary RGB pixel structure according to embodiments of the present technology.

FIGS. 4A-4B show graphs of exemplary first and second bandpass filters according to embodiments of the present technology.

### BRIEF SUMMARY

Embodiments of the present technology include pixel structures. The pixel structures include a light emitting diode structure to generate ultraviolet light. The pixel structures further include a photoluminescent region containing a photoluminescent material. The pixel structures additionally include a first bandpass filter positioned between the light emitting diode structure and the photoluminescent region, where the first bandpass filter is operable to transmit ultraviolet light. The pixel structures yet additionally include a second bandpass filter positioned on an opposite side of the photoluminescent region as the first bandpass filter, where the second bandpass filter is operable to transmit visible light.

In additional embodiments, the photoluminescent region of the pixel structures may include a first side adjacent to the first bandpass filter and a second side adjacent to the second bandpass filter, where the second side of the photoluminescent region is wider than the first side. In further embodiments, the photoluminescent region may further include a first sidewall in contact with the first bandpass filter, where the first sidewall and the first bandpass filter are characterized by a tilting angle of greater than 90°. In still further embodiments, the pixel structures may include a microlens structure, where the second bandpass filter is positioned between the microlens structure and the photoluminescent region. In yet additional embodiments, the pixel structures may include a protection region positioned between the light emitting diode structure and the first bandpass filter. In more embodiments, the photoluminescent material in the photoluminescent region of the pixel structures may include a quantum dot material operable to absorb a first wavelength of light from the light emitting diode structure and emit a second wavelength of light that is longer than the first wavelength of light. In still more embodiments, the photoluminescent region is characterized by a depth between the first side and the second side that is greater than or about 1 μm. In yet more embodiments, the first side of the photoluminescent region is characterized by a width across the photoluminescent region of less than or about 30 μm.

Additional embodiments of the present technology include additional pixel structures. The pixel structures include a light emitting diode structure operable to generate ultraviolet light, and a photoluminescent region positioned over the light emitting diode structure. The photoluminescent region is characterized by a depth between a first side and a second side of the photoluminescent region, where the first side of the photoluminescent region is shorter than the second side.

In further embodiments, the photoluminescent region of the pixel structures includes a third side that includes a sidewall region between the first side and the second side of the photoluminescent region, where a tilting angle between the first side and the third side is greater than 90°. In still further embodiments, the first side of the photoluminescent region is characterized by a width of less than or about 4 μm. In additional embodiments, the first side of the photoluminescent region is adjacent to a short bandpass filter positioned between the light emitting diode structure and the photoluminescent region, where the short bandpass filter is operable to transmit ultraviolet light, and where the second side of the photoluminescent region is adjacent to a long bandpass filter positioned on an opposite side of the photoluminescent region, where the long bandpass filter is operable to transmit visible light. In additional embodiments, the photoluminescent region of the pixel structures may include a photoluminescent material that includes a quantum dot material operable to absorb a first wavelength of light from the light emitting diode structure and emit a second wavelength of light that is longer than the first wavelength of light.

Further embodiments of the present technology include display components. The display components have a plurality of pixel structures, where each of the pixel structures includes a light emitting diode structure operable to generate ultraviolet light and a photoluminescent region containing a photoluminescent material. The pixel structures further include a first bandpass filter between the light emitting diode structure and the photoluminescent region, where the first bandpass filter is operable to transmit ultraviolet light. The pixel structures additionally include a second bandpass filter positioned on an opposite side of the photoluminescent region as the first bandpass filter, where the second bandpass filter is operable to transmit visible light.

In more embodiments, the pixel structures further include a first side of the photoluminescent region adjacent to the first bandpass filter and a second side of the photoluminescent region adjacent to the second bandpass filter, where the second side is wider than the first side, and where the photoluminescent region further includes a first sidewall in contact with the first bandpass filter, and the first sidewall and the first bandpass filter are characterized by a tilting angle of greater than 90°. In yet more embodiments, the photoluminescent material in the photoluminescent region of the pixel structures includes a quantum dot material operable to absorb a first wavelength of light from the light emitting diode structure and emit a second wavelength of light that is shorter than the first wavelength of light, and the light emitting diode structure is a micro-light emitting diode structure. In further embodiments, the display component is characterized by a pixel density of greater than or about 3000 pixels-per-inch (ppi). In still further embodiments, the display component is characterized by an optical density of greater than or about 1. In additional embodiments, the display component is operable to be incorporated into an augmented reality display device.

The present technology provides several benefits over conventional designs for pixel structures and the display components that incorporate them. In many conventional designs, the pixel structures lack a short bandpass filter between the UV-generating light-emitting-diode structure and the bottom of the photoluminescent region and lack a long bandpass filter at the top of the photoluminescent region. Many conventional designs also have the sidewalls formed at right angles (i.e., a 90° tilting angle) to the top and bottom sides of the photoluminescent region. These design characteristics lead to a reduced fraction of the visible light generated in the photoluminescent region contributing to a displayed image. In embodiments of the present technology, a short bandpass filter is positioned between a UV-generating light-emitting-diode structure and the bottom of the photoluminescent region to reflect more visible light into the photoluminescent region and out to the displayed image. Further embodiments of the present technology include a long bandpass filter positioned at the top of the photoluminescent region to reflect UV light back into the photoluminescent region while permitting visible light to pass to the displayed image. Still further embodiments of the present technology widen a top side of the photoluminescent region where the visible light passes to form a displayed image relative to the bottom side of the photoluminescent region positioned adjacent to the light-emitting-diode structure. The widened top side of the photoluminescent region relative to the bottom side permits more of the visible light to pass to the image relative to a conventional photoluminescent region where the top and bottom sides have the same widths. These and other embodiments, along with many of their advantages and features, are described in more detail in conjunction with the below description and attached figures.

### DETAILED DESCRIPTION

Technological advances in high-resolution displays include the development of micro-light-emitting-diodes (μLEDs) from inorganic semiconductor materials and the use of photoluminescent materials like quantum dots in the displays. μLEDs are made of layers of semiconductor materials, such as indium gallium nitride (InGaN), that can be arranged to emit light of a specific peak emission wavelength when excited by an applied electric field. Semiconductor fabrication processes are used to make μLEDs having a longest dimension of less than or about 50 μm and operable to emit red, green, or blue light. Quantum dots are nanometer-sized particles of inorganic materials that can emit light of a particular color after being excited by more energetic light. The color of the emitted light may depend on one or more characteristics of the particles, including their size, shape, and composition, among other characteristics. For quantum dots made of inorganic semiconductor materials, the color of the light they emit depends on an energy gap between the conduction band and the valence band of the dots. When the quantum dots are excited, one or more electrons jump from the lower-energy conduction band to the higher-energy valence band. As the excited electrons fall back down to the conduction band, they emit light having a color that depends on the size of the energy gap between the valence band and the conduction band. The narrower the energy gap, the more the emitted light is shifted to the red, while the wider the energy gap, the more the emitted light is shifted to the blue. By adjusting one or more characteristics of the quantum dots that change the energy gap between the conduction and valence bands, quantum dots can be made that emit light of practically any color in the visible spectrum.

Additional advances have combined μLEDs and quantum dots in a high-resolution display. The μLEDs are independently switched on and off by electronic circuitry in a backplane control panel to generate source light that photoexcites the quantum dots. The more energetic μLED source light, such as blue or ultraviolet light, excites the quantum dots and causes them to emit light of a specific, less-energetic, color such as blue, green, orange, or red light. The excited quantum dots can emit light with improved emissions characteristics, such as a narrower band full-width-half-maximum wavelength spectrum, than the μLEDs. The ability of the quantum dots to emit a sharper color of light reduces the number of color filters and polarizers needed in a display to block unwanted colors of light from contaminating the displayed images.

Unfortunately, the quantum dots emit the visible light equally in all directions (i.e., they emit the light isotropically). This results in a significant portion of the emitted light being directed away from an imaging direction where the light is incorporated into a displayed image. As the widths of the photoluminescent regions decrease faster than their depths to increase the pixel density of the display component, an increasing fraction of the light emitted from the quantum dots is directed away from the imaging direction. Consequently, there can be a tradeoff between increasing the pixel density and decreasing the brightness of the displayed image. Addressing this tradeoff by increasing the power to the μLEDs so they provide more UV light reduces the power efficiency of the display component and increases the waste heat. For device components positioned close to a viewer's eyes, like virtual reality and augmented reality wearable devices, the increased heat can make the device uncomfortable or unwearable.

The present technology addresses these and other problems with the design of conventional stacked LED and luminescent material structures that loose too much light to emission in non-productive directions. In embodiments, the present technology includes a pixel structure with a first bandpass filter positioned between a light emitting diode structure operable to generate UV light, and a photoluminescent region containing a photoluminescent material such as an inorganic quantum dot or an organic light emitting compound. The first bandpass filter is operable to transmit ultraviolet light but block visible light. In embodiments, this first bandpass filter may be called a short bandpass filter. In further embodiments, the first bandpass filter may function as both a window to transmit UV light emitted from the light emitting diode structure and a reflector to reflect visible light back into the photoluminescent region that is emitted in a non-productive direction from the photoluminescent materials contained in the region. The first bandpass filter facilitates the excitation of the photoluminescent material with the UV light from the LED structure and also increases the amount of visible light moving in the image display direction that is emitted by the excited photoluminescent material. In embodiments, the present technology also includes a pixel structure with a second bandpass filter positioned on an opposite side of the photoluminescent region as the first bandpass filter. The second bandpass filter is operable to transmit visible light but block ultraviolet light. In additional embodiments, the second bandpass filter may function as both a window to transmit visible light emitted from the photoluminescent region to a displayed image and a reflector to reflect UV light back into the photoluminescent region that was not absorbed in an earlier pass. In embodiments, the present technology still also includes a photoluminescent region having a first side adjacent to the first bandpass filter that is wider than a second side adjacent to the second bandpass filter. The wider first side than second side of the photoluminescent region creates a tilting angle between a sidewall and second side that is not a right angle and is greater than 90°. The present structure can also facilitate more visible light in the direction of the displayed image from the photoluminescent region of the pixel structure.

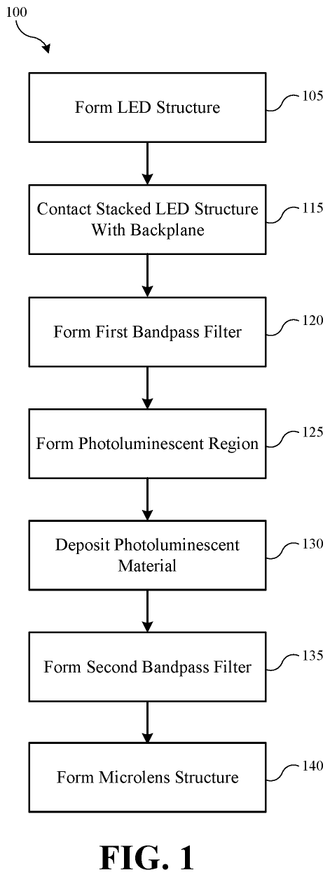

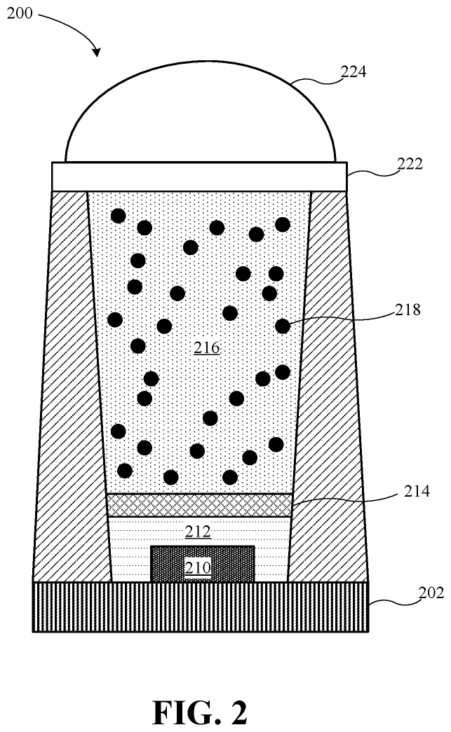

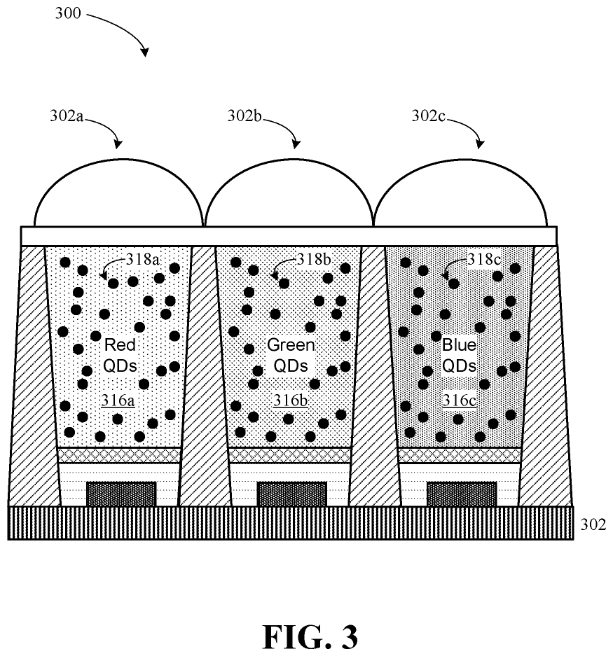

FIG. 1 shows a flowchart with selected operations in method 100 of fabricating a pixel according to embodiments of the present technology. Method 100 may or may not include one or more operations prior to the initiation of the method, including front-end processing, deposition, etching, polishing, cleaning, or any other operations that may be performed prior to the described operations. The method may include optional operations, which may or may not be specifically associated with some embodiments of methods according to the present technology. Method 100 describes operations to form embodiments of pixel structures, one of which is shown in a simplified schematic form as a single pixel structure 200 in FIG. 2 and another of which is shown as an RGB pixel structure 300 in FIG. 3. The cross-sectional view of pixel structures 200 and 300 in FIGS. 2 and 3 is a split-open cross-sectional view that shows the pixel structure that is cut between a first and second pair of subpixels and split open to reveal a cross-sectional liner arrangement of red, green, blue pixels. FIGS. 2 and 3 illustrate only partial schematic views with limited details. In further embodiments that are not illustrated, exemplary pixel structures may contain additional layers, regions, and materials, having aspects as illustrated in the figures, as well as alternative structural and material aspects that may still benefit from any of the aspects of the present technology.

Method 100 includes forming a LED structure 210 on a substrate 202 at operation 105. In embodiments, the LED structure 210 may be a μLED structure operable to emit blue light or ultraviolet light. In some embodiments the substrate 202 may be removed to expose a surface upon which a photoluminescent region is formed and the LED structure 210 may be operable to emit ultraviolet light. In additional embodiments the substrate 202 may form a backplane in electronic communication with the LED structure 210 and the LED structure may be operable to emit blue light having a peak emission wavelength in the visible blue portion of the visible spectrum. In further embodiments, the LED structure 210 may be operable to emit light characterized by a peak emission wavelength of less than or about 400 nm, less than or about 390 nm, less than or about 380 nm, less than or about 370 nm, less than or about 360 nm, less than or about 350 nm, less than or about 340 nm, less than or about 330 nm, or less. In the embodiment of pixel structure 200 shown in FIG. 2, the LED structure 210 formed on substrate 202 is operable to emit ultraviolet (UV) light.

In embodiments, the LED structure 210 may be a gallium-and-nitrogen-containing LED structure. In further embodiments, the LED structure 210 may be a gallium nitride LED structure that is epitaxially formed on a substrate or a previously formed LED structure. In additional embodiments, the substrate 202 may be a silicon substrate or a sapphire substrate, among other kinds of substrates. In still additional embodiments, the LED structure 210 may further include an n-doped GaN layer and a p-doped GaN layer. Formed between the n-doped and p-doped GaN layers is a multiple-quantum-well (MQW) region where the light emitted by the LED structure 210 is generated. The LED structure 210 may further include an electrically conductive N-pad contact that forms a pathway for electrical current to pass through the n-doped GaN layer. The LED structure 210 may also include an electrically conductive P-pad contact that forms a pathway for electrical current to pass through the p-doped GaN layer. The N-pad and P-pad contacts may be connected to electrically conducive layers in an LED subpixel or directly connected to contacts in the control circuitry of a backplane. In embodiments, electrical signals from the control circuitry create a flow of electrical current through the LED structure 210 that causes light emission from the MQW regions of the structures. In additional embodiments, the MQW region is formed to emit light characterized by a repeatable peak intensity wavelength and quantum efficiency for an applied electrical signal (e.g., electrical current and/or voltage). In embodiments, the peak intensity wavelength of the light emitted from the MQW region may be an ultraviolet light wavelength (e.g., a wavelength of light less than or about 400 nm).

Method 100 may further include contacting the LED structure 210 with a backplane (not shown) at operation 115. In embodiments, the backplane may include a contact formed in semiconductor layer that addresses the LED structure 210. In embodiments, the contact may be made of an electrically conductive material such as copper, aluminum, gold, tungsten, chromium, or nickel, among other electrically conductive materials. In still further embodiments, the LED structure 210 may be positioned between one or more transparent electrically conductive layers that form part of the electrical conduction pathway between the LED structure and the contacts in the backplane. In additional embodiments, the transparent conductive layers may be made of indium tin oxide or indium zinc oxide, among other transparent conductive materials. In yet further embodiments, a mirror layer (not shown) may be positioned adjacent to the one or more transparent electrical layers to reflect light emitted by the LED structure 210 towards the photoluminescent region 216. In more embodiments, the mirror layer may be made of one or more reflective metals such as copper, aluminum, chromium, silver, platinum, or molybdenum, among other reflective metals. In still further embodiments, an electrically conductive bonding layer (not shown) that bonds the LED substrate 202 to the backplane may be positioned between the mirror layer and the backplane. In more embodiments, the electrically conductive bonding layer may be made of one or more conductive materials such as tin, gold, or indium, among other conductive materials.

In embodiments, a protection layer 212 may be formed on the LED structure 210. In additional embodiments, the protection layer 212 hinders or prevents moisture and other compounds from contacting the LED structure 210 while permitting the transmission of light from the LED structure through the first bandpass filter 214 and into the photoluminescent region 216. In further embodiments, the protection layer 212 may include a silicon-containing dielectric material such as silicon oxide. In still further embodiments, the protection layer may be characterized by a depth between the LED structure 210 and the first bandpass filter 214 of less than or about 2 μm, less than or about 1.5 μm, less than or about 1 μm, less than or about 0.75 μm, less than or about 0.5 μm, less than or about 0.4 μm, less than or about 0.3 μm, less than or about 0.2 μm, less than or about 0.1 μm, or less.

Method 100 may still further include forming a first bandpass filter 214 in the pixel structure 200 at operation 120. In embodiments, the first bandpass filter may be positioned between the LED structure 210 and the photoluminescent region 216. In additional embodiments, the first bandpass filter may be formed on the LED structure 210, or if present, the protection layer 212. In more embodiments, the first bandpass filter 214 may be characterized as a short bandpass filter operable to transmit a greater percentage of light having a wavelength less than or about a UV wavelength compared to visible wavelengths. In still more embodiments, the first bandpass filter 214 may be operable to transmit greater than 50%, greater than or about 60%, greater than or about 70%, greater than or about 80%, greater than or about 90%, of ultraviolet light. In additional embodiments, the first bandpass filter 214 may be operable to transmit less than 50%, less than 40%, less than 30% less than 20%, less than 10%, less than 5%, less than 1%, or less of visible light.

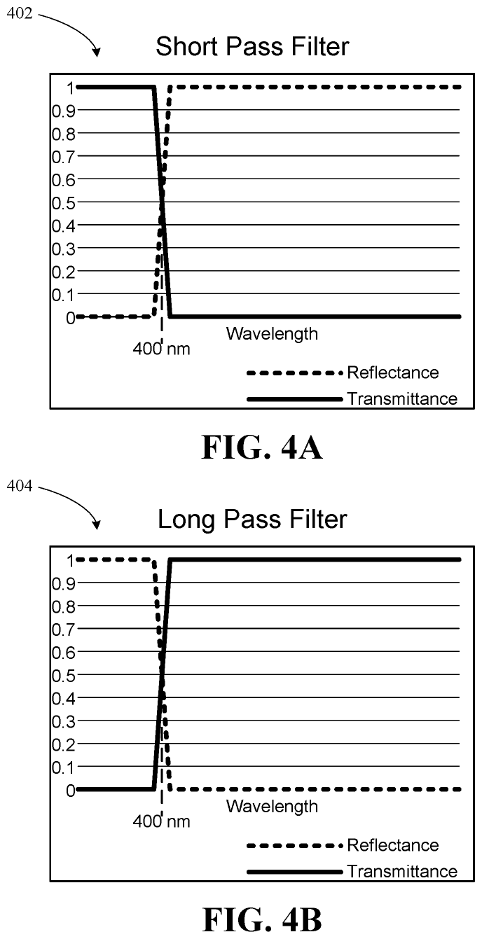

FIG. 4A shows an exemplary light reflectance and transmittance profiles for an embodiment of a first bandpass filter 214. The profile shows light with wavelengths significantly shorter than 400 nm are transmitted through the filter to the photoluminescent region 216, while light with wavelengths significantly longer than 400 nm is reflected towards the LED structure 210. In other embodiments, the transmission profile of the first bandpass filter 214 may have a 50% transmission/reflection wavelength that is shorter or longer than 400 nm. In these embodiments, light with wavelengths significantly shorter than the 50% transmission/reflection wavelength are transmitted through the filter to the photoluminescent region 216, while light with wavelengths significantly longer than the 50% transmission/reflection wavelength is reflected towards the LED structure 210. In additional embodiments, the first bandpass filter 214 may be characterized by a 50% transmission/reflection wavelength that is less than 400 nm, less than or about 390 nm, less than or about 380 nm, less than or about 370 nm, or less. In further embodiments, the first bandpass filter 214 may be characterized by a 50% transmission/reflection wavelength that is greater than 400 nm, greater than or about 410 nm, greater than or about 420 nm, greater than or about 430 nm, or more. From the perspective of the photoluminescent region 216, shorter wavelength UV light moving in the direction of the LED structure 210 is reflected into the photoluminescent region. This permits a greater percentage of the UV light emitted by the LED structure 210 to be absorbed by the photoluminescent material 218 in the photoluminescent region 216.

Method 100 may also include forming a photoluminescent region 216 in the pixel structure 200 at operation 125. In embodiments, the photoluminescent region 216 may include one or more photoluminescent materials 218, such as quantum dots, that are operable to absorb light emitted from the LED structure 210 and emit light with specific color characteristics. In embodiments, the photoluminescent region 216 may be formed in part from pixel isolation structures 220a-b. In further embodiments, the pixel isolation structures 220a-b reduce the crosstalk generated by light from adjacent and nearby pixel structures. In embodiments, the reduction in the intensity of light from adjacent and nearby pixel structures may be greater than or about 50%, greater than or about 60%, greater than or about 70%, greater than or about 80%, greater than or about 90%, greater than or about 95%, greater than or about 99%, or more.

In further embodiments, the pixel isolation structures 220a-b may extend above and around the LED structure 210. In yet further embodiments, the subpixel isolation structures may extend adjacent to and below the contact regions for the LED structure 210 and may further extend down to the backplane of the pixel structure. In more embodiments, the subpixel isolation structures 220a-b may include a core column of pixel isolation material that is covered by one or more additional layers of material, such as a layer of reflective material such as aluminum or copper. In embodiments, the material in the core column may include a metal or a dielectric material, among other types of materials. In further embodiments, the metal material may include one or more of silicon, tungsten, copper, and aluminum, among other metals. In yet further embodiments, the dielectric material may include one or more of silicon oxide, silicon nitride, silicon carbide, a photoresist material, or a dielectric organic-polymer material, among other dielectric materials. In still further embodiments, the pixel isolation structures 220a-b may have a height of greater than or about 2.5 μm, greater than or about 5 μm, greater than or about 7.5 μm, greater than or about 10 μm, greater than or about 12.5 μm, greater than or about 15 μm, greater than or about 17.5 μm, greater than or about 20 μm, or more. In yet additional embodiments, the pixel isolation structures 220a-b may have a width of less than or about 5 μm, less than or about 4.5 μm, less than or about 4 μm, less than or about 3.5 μm, less than or about 3 μm, less than or about 2.5 μm, less than or about 2 μm, or less. In still further embodiments the pixel isolation structures 220a-b may have a height-to-width aspect ratio that is greater than or about 1.5:1, greater than or about 2:1, greater than or about 2.5:1, greater than or about 3:1, greater than or about 3.5:1, greater than or about 4:1, greater than or about 4.5:1, greater than or about 5:1, or more. In the embodiment shown in FIG. 2, pixel structure 200 includes pixel isolation structures 220a-b.

In embodiments, the pixel isolation structures 220a-b form sidewalls of the photoluminescent region 216 that also includes a first side adjacent to the first bandpass filter 214 and a second side opposite the first side and adjacent to the second bandpass filter 222. In further embodiments, a first width of the first side, extending between pixel isolation structure 220a to pixel isolation structure 220b, is less than a second width of the second side extending between the same pixel isolation structures 220a-b. In additional embodiments, the first width may be less than or about 4 μm, less than or about 3.5 μm, less than or about 3 μm, less than or about 2.5 μm, less than or about 2 μm, less than or about 1.5 μm, less than or about 1 μm, or less. The difference in the first and second widths of the first and second sides of the photoluminescent region 216 creates a tilting angle (a) between the pixel isolation structure 220b and the first side that is greater than 90° (i.e., not a right angle). In embodiments, the tilting angle (a) may be characterized as greater than 90°, greater than 90.5°, greater than 91°, greater than 91.5°, greater than 92°, greater than 92.5°, greater than 93°, or more. The greater width of the second side of the photoluminescent region 216 adjacent to the second bandpass filter 222 creates a larger area for visible light to exit the photoluminescent region and be incorporated into the displayed image.

Method 100 still further includes depositing photoluminescent material 218 in the photoluminescent region 216 of the pixel structure 200 at operation 130. In embodiments, the as-deposited photoluminescent material may include one or more photoluminescent precursors in a mixture or slurry that includes a photo-curable fluid and one or more photoluminescent particles or compounds. In further embodiments, the one or more photoluminescent compounds may include quantum dot materials that are operable to emit light with specific color characteristics when excited by a source light. In additional embodiments, these quantum-dot materials may include nanoparticles made of one or more kinds of inorganic semiconductor materials such as indium phosphide, zinc selenide, zinc sulfide, silicon, silicates, and graphene, and doped inorganic oxides, among other semiconductor materials. In more embodiments, the photo-curable fluid may include one or more cross-linkable compounds, a photo-initiator, and a color conversion agent. In additional embodiments, the cross-linkable compounds may include monomers that form a polymer when cured. In more embodiments, the monomers may include acrylate monomers, methacrylate monomers, and acrylamide monomers. In yet more embodiments, the cross-linkable compounds may include a negative photoresist material such as SU-8 photoresist. In further embodiments, the photo-initiator may include phosphine oxide compounds and keto compounds, among other kinds of photo-initiator compounds that generate radicals that initiate the curing of unsaturated compounds when excited by ultraviolet light. Commercially available photo-initiator compounds include Irgacure 184, Irgacure 819, Darocur 1173, Darocur 4265, Darocur TPO, Omnicat 250, and Omnicat 550, among other photo-initiators.

When the as-deposited photoluminescent material includes one or more photoluminescent precursors, the precursors may be cured to form a photoluminescent material 218. In embodiments, the curing operation may include exposing the photoluminescent precursor in the photoluminescent region 216 to a curing light that coverts the photoluminescent precursor into the photoluminescent material 218. In still further embodiments, the curing light may be characterized by a peak emission wavelength short enough to activate one or more of the photo-curable compounds in the photo-curable fluid of the photoluminescent precursor. In yet more embodiments, the curing light may be characterized by a peak emission wavelength of less than or about 405 nm, less than or about 400 nm, less than or about 395 nm, less than or about 390 nm, less than or about 385 nm, less than or about 380 nm, less than or about 375 nm, less than or about 370 nm, less than or about 365 nm, less than or about 360 nm, less than or about 355 nm, less than or about 350 nm, less than or about 340 nm, less than or about 330 nm, less than or about 320 nm, less than or about 310 nm, less than or about 300 nm, or less. In still further embodiments, the curing light may be supplied by the LED structure 210. In these embodiments, supplying the curing light from the LED structure 210 may permit the self-alignment of the photoluminescent material 218 in the photoluminescent region 216 with the LED structure 210. The self-alignment of the photoluminescent material with the LED structure is increasingly beneficial as the size of the subpixels decreases and the pixel density increases.

Method 100 may still further include forming a second bandpass filter 222 in the pixel structure 200 at operation 135. In embodiments, the second bandpass filter 222 may be positioned between the photoluminescent region 216 and the microlens 224. In additional embodiments, the second bandpass filter 222 may be formed on the photoluminescent region 216, or if present, a UV filter (not shown). In more embodiments, the second bandpass filter 222 may be characterized as a long bandpass filter operable to transmit a greater percentage of light having a wavelength in the visible wavelength region compared to shorter UV wavelengths. In still more embodiments, the second bandpass filter 222 may be operable to transmit greater than 50%, greater than or about 60%, greater than or about 70%, greater than or about 80%, greater than or about 90%, of visible light. In additional embodiments, the second bandpass filter 222 may be operable to transmit less than 50%, less than 40%, less than 30% less than 20%, less than 10%, less than 5%, less than 1%, or less of ultraviolet light.

FIG. 4B shows an exemplary light reflectance and transmittance profiles for an embodiment of a second bandpass filter 222. The profile shows light with wavelengths significantly longer than 400 nm are transmitted through the filter to the microlens 224 and displayed image, while light with wavelengths significantly shorter than 400 nm is reflected towards the photoluminescent region 216. In additional embodiments, the transmission profile of the second bandpass filter 222 may have a 50% transmission/reflection wavelength that is shorter or longer than 400 nm. In these embodiments, light with wavelengths significantly longer than the 50% transmission/reflection wavelength are transmitted through the filter to the microlens 224, while light with wavelengths significantly shorter than the 50% transmission/reflection wavelength is reflected towards the photoluminescent region 216. In additional embodiments, the second bandpass filter 222 may be characterized by a 50% transmission/reflection wavelength that is less than 400 nm, less than or about 390 nm, less than or about 380 nm, less than or about 370 nm, or less. In further embodiments, the second bandpass filter 222 may be characterized by a 50% transmission/reflection wavelength that is greater than 400 nm, greater than or about 410 nm, greater than or about 420 nm, greater than or about 430 nm, or more. From the perspective of the photoluminescent region 216, shorter wavelength UV light moving in the direction of the microlens 224 is reflected back to the photoluminescent region. This permits a greater percentage of the UV light emitted by the LED structure 210 to be absorbed by the photoluminescent material 218 in the photoluminescent region 216.

In embodiments, the second bandpass filter 222 functions as a UV filter to block UV light from exiting the photoluminescent region in the direction of the displayed image. In additional embodiments, a UV filter (not shown) may be positioned adjacent to the second bandpass filter 222 to attenuate or block additional UV light from reaching the displayed image. In more embodiments, the UV filter may be a dielectric layer that absorbs UV light generated by the stacked LED structure 210 in the pixel structure 200 while transmitting the visible light emitted by the photoluminescent material 218 in the photoluminescent region 216. In further embodiments, the dielectric layer may be a silicon oxide layer deposited by chemical vapor deposition or physical vapor deposition. In still additional embodiments, the UV filter may be made from organic polymers such as polyacrylates, polymethyl methacrylates, and copolymers of polyacrylates and polymethyl methacrylates. In yet further embodiments, the UV filter may be made from commercially available materials such as Tinuvin CarboProtect from BASF, and the Eversorb series from Everlight. In embodiments, the UV filter may reduce the percentage of UV light in the total light emitted from the pixel structure to less than or about 5%, less than or about 2.5%, less than or about 1%, less than or about 0.5%, less than or about 0.1%, less than or about 0.05%, less than or about 0.01%, or less. In additional embodiments, the UV filter may transmit visible light from the pixel structure at greater than or about 50%, greater than or about 75%, greater than or about 85%, greater than or about 90%, greater than or about 95%, greater than or about 99%, or more.

Method 100 still also includes forming a microlens 224 in the pixel structure 200 at operation 140. In embodiments, the microlens 224 may be positioned adjacent to the second bandpass filter 222 and, if present, the UV filter. In additional embodiments, the microlens 224 may be convex-shaped lenses, concave-shaped lenses, Fresnel-shaped lenses, among other lens shapes. In further embodiments, the microlens 224 may be made of inorganic or organic materials that can transmit the visible light emitted from the pixel structure 200. In additional embodiments, the microlens 224 may be made of polymers such as polydimethylsiloxanes, polyacrylates, polymethyl methacrylates, polybutyl methacrylates, polystyrenes, and poly(benzyl methacrylates), among other polymers. In more embodiments, the microlens 224 may be made of inorganic materials such as silica, zinc oxide, and aluminum oxide, among other inorganic materials. The microlens 224 bends and focuses the light emitted by the pixel structure to increase image quality from a display component for devices such as VR headsets and AR glasses, among other devices. In the embodiment shown in FIG. 2, pixel structure 200 includes microlens 224.

Referring now to FIG. 3, another pixel structure 300 according to embodiments of the present technology is shown. Pixel structure 300 includes three subpixel structures 302a-c with photoluminescent materials 318a-c operable to emit light of red, green, and blue wavelengths, respectively. In embodiments, the formation of the photoluminescent materials 318a-c in the photoluminescent regions 316a-c may include sequential operations to form photoluminescent material operable to emit light characterized by a specific peak intensity wavelength in one of the subpixels 302a-c of the pixel structure 300. In further embodiments, the sequential operations may include forming first photoluminescent material 318a that includes red light emitting quantum dots in a first photoluminescent region 316a of the pixel structure 300, forming a second photoluminescent material 318b that includes green light emitting quantum dots in a second photoluminescent region 316b of the pixel structure, and forming a third photoluminescent material 318c that includes blue light emitting quantum dots in a third photoluminescent region 316c of the pixel structure. In yet more embodiments, a fourth subpixel structure (not shown) may be included in the pixel structure 300. The fourth subpixel may not include a photoluminescent material unless one of the other subpixel structures 302a-c fails to illuminate properly.

In embodiments, the pixel structures 200 and 300 may be incorporated with additional pixel structures to form a display component. In further embodiments, the display component may be incorporated into a display device such as a headset, glasses, a screen, or a monitor, among other display devices. In still further embodiments, the display component containing the present pixel structures may be incorporated into a display device for virtual reality and/or augmented reality service.

In further embodiments, the display component incorporating the present pixel structures may be characterized by a pixel density of greater than or about 500 pixels per inch (ppi), greater than or about 1000 ppi, greater than or about 1500 ppi, greater than or about 2000 ppi, greater than or about 2500 ppi, greater than or about 3000 ppi, greater than or about 3500 ppi, greater than or about 4000 ppi, greater than or about 4500 ppi, greater than or about 5000 ppi, or more. In more embodiments, the increased pixel density of the display component does not result in a decrease brightness of a displayed image generated by the display component. In embodiments, the image brightness may be characterized as greater than or about 100 nits, greater than or about 250 nits, greater than or about 500 nits, greater than or about 750 nits, greater than or about 1000 nits, greater than or about 2500 nits, or more. In still further embodiments, the pixel structures of the present technology may be characterized by an optical density of greater than or about 0.5, greater than or about 0.75, greater than or about 0.8, greater than or about 0.9, greater than or about 0.95, greater than or about 0.99, or more.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the pixel structure” includes reference to one or more pixel structures and equivalents thereof known to those skilled in the art, and so forth.

Also, the words “comprise”, “comprising”, “include”, “including”, and “includes” when used in this specification and in the following claims are intended to specify the presence of stated features, integers, components, or steps, but they do not preclude the presence or addition of one or more other features, integers, components, steps, acts, or groups.

What is claimed is:

1. A pixel structure comprising:
a light emitting diode structure operable to generate ultraviolet light;
a photoluminescent region containing a photoluminescent material;
a first bandpass filter positioned between the light emitting diode structure and the photoluminescent region, wherein the first bandpass filter is operable to transmit ultraviolet light; and
a second bandpass filter positioned on an opposite side of the photoluminescent region as the first bandpass filter, wherein the second bandpass filter is operable to transmit visible light.

2. The pixel structure of claim 1, wherein the photoluminescent region includes a first side adjacent to the first bandpass filter and a second side adjacent to the second bandpass filter, wherein the second side of the photoluminescent region is wider than the first side.

3. The pixel structure of claim 2, wherein the photoluminescent region further includes a first sidewall in contact with the first bandpass filter, and wherein the first sidewall and the first bandpass filter are characterized by a tilting angle of greater than 90°.

4. The pixel structure of claim 1, wherein the pixel structure further comprises a microlens structure, and wherein the second bandpass filter is positioned between the microlens structure and the photoluminescent region.

5. The pixel structure of claim 1, wherein the pixel structure further comprises a protection region positioned between the light emitting diode structure and the first bandpass filter.

6. The pixel structure of claim 1, wherein the photoluminescent material in the photoluminescent region comprises a quantum dot material operable to absorb a first wavelength of light from the light emitting diode structure and emit a second wavelength of light that is longer than the first wavelength of light.

7. The pixel structure of claim 2, wherein the photoluminescent region is characterized by a depth between the first side and the second side that is greater than or about 1 μm.

8. The pixel structure of claim 7, wherein the first side is further characterized by a width across the photoluminescent region of less than or about 30 μm.

9. A pixel structure comprising:
a light emitting diode structure operable to generate ultraviolet light; and
a photoluminescent region positioned over the light emitting diode structure, wherein the photoluminescent region is characterized by a depth between a first side and a second side of the photoluminescent region, and wherein the first side of the photoluminescent region is shorter than the second side.

10. The pixel structure of claim 9, wherein the photoluminescent region includes a third side that includes a sidewall region between the first side and the second side of the photoluminescent region, and wherein a tilting angle between the first side and the third side is greater than 90°.

11. The pixel structure of claim 9, wherein the first side is characterized by a width of less than or about 4 μm.

12. The pixel structure of claim 9, wherein the first side is characterized by a width of greater than 4 μm.

13. The pixel structure of claim 9, wherein the first side is adjacent to a short bandpass filter positioned between the light emitting diode structure and the photoluminescent region, and wherein the short bandpass filter is operable to transmit ultraviolet light, and wherein the second side is adjacent to a long bandpass filter positioned on an opposite side of the photoluminescent region as the short bandpass filter, and wherein the long bandpass filter is operable to transmit visible light.

14. The pixel structure of claim 9, wherein the photoluminescent region includes a photoluminescent material comprising a quantum dot material operable to absorb a first wavelength of light from the light emitting diode structure and emit a second wavelength of light that is longer than the first wavelength of light.

15. A display component comprising:
a plurality of pixel structures, wherein each of the pixel structures comprises:
a light emitting diode structure operable to generate ultraviolet light;
a photoluminescent region containing a photoluminescent material;
a first bandpass filter positioned between the light emitting diode structure and the photoluminescent region, wherein the first bandpass filter is operable to transmit ultraviolet light; and
a second bandpass filter positioned on an opposite side of the photoluminescent region as the first bandpass filter, wherein the second bandpass filter is operable to transmit visible light.

16. The display component of claim 15, wherein the pixel structures further include a first side of the photoluminescent region adjacent to the first bandpass filter and a second side of the photoluminescent region adjacent to the second bandpass filter, wherein the second side is wider than the first side, and wherein the photoluminescent region further includes a first sidewall in contact with the first bandpass filter, and the first sidewall and the first bandpass filter are characterized by a tilting angle of greater than 90°.

17. The display component of claim 15, wherein, in each of the pixel structures, the photoluminescent material in the photoluminescent region comprises a quantum dot material operable to absorb a first wavelength of light from the light emitting diode structure and emit a second wavelength of light that is shorter than the first wavelength of light, and the light emitting diode structure is a micro-light-emitting diode structure.

18. The display component of claim 15, wherein the display component is characterized by a pixel density of greater than or about 3000 pixels-per-inch.

19. The display component of claim 15, wherein the display component is characterized by an optical density of greater than or about 1.

20. The display component of claim 15, wherein the display component is operable to be incorporated into an augmented reality display device.
